(19) United States
(12) Patent Application Publication
(10) Pub. No.: US 2006/0216872 A1
(43) Pub. Date: Sep. 28, 2006

(54) Method of manufacturing a semiconductor device having an organic thin film transistor

(76) Inventors: Tadashi Arai, Kumagaya (JP); Shinichi Saito, Kawasaki (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/209,612

(22) Filed: Aug. 24, 2005

(30) Foreign Application Priority Data
Mar. 24, 2005 (JP) 2005-085288

(51) Int. Cl. H01L 21/84; H01L 21/00

(52) U.S. Cl. 438/149

(57) ABSTRACT

Since positional displacement occurs in a case of using a printing method, an electrode substrate in which a lower electrode and an upper electrode are accurately positioned by way of an insulator could not be formed. Use of a photomask for positional alignment increases the cost outstandingly. According to the present invention, since the lower electrode is utilized as a photomask for positionally alignment with the upper electrode, positional displacement does not occur even by the use of the printing method. Accordingly, a semiconductor device such as a flexible substrate using the organic semiconductor can be formed at a reduced cost by using a printing method.

The present invention claims priority from Japanese application JP 2005-085288 filed on Mar. 24, 2005, the content of which is hereby incorporated by reference into this application.

### BACKGROUND OF THE INVENTION

1. Field of the Invention

The present invention relates to a method of manufacturing a semiconductor device having an organic thin film transistor.

2. Description of the Related Art

In recent years, various research and development have been conducted for display devices having thin film transistor (TFT) devices. Since TFTs consume less electric power and can save space, they have now been started for use as display device driving transistors for portable equipment such as mobile telephones, laptop personal computers, and PDAs. Most of such TFTs have been manufactured from inorganic semiconductor materials typically represented by crystalline silicon or amorphous silicon. This is because of the merit in which they can be manufactured by using existent manufacturing steps and manufacturing techniques for semiconductor devices. However, in a case of using the semiconductor manufacturing step, since the processing temperature during formation of a semiconductor film is 350° C. or higher, a restriction is imposed on substrates that can be formed. In particular, since most of flexible substrates have a heat resistant temperature of 350° C. or lower, it is difficult to manufacture TFTs from inorganic semiconductor materials by using usual semiconductor manufacturing steps.

On the other hand, research and development on TFT devices using organic semiconductor materials (hereinafter simply referred to as organic TFT), which can be manufactured at low temperatures, have been proceeded recently. Since the organic TFT has an organic semiconductor film, which can be formed at low temperatures, it can be formed also on a substrate that bends flexibly such as a plastic material. Accordingly, a new flexible device not found in the prior art can be manufactured.

The method of forming an organic semiconductor film employed when an organic TFT is formed depends on the organic semiconductor material per se, and is selected as a most suitable method from a printing method such as a ink jet method, a spin coating method, a spray method, a vapor deposition method, a dipping method and a casting method. In particular, a low molecular compound such as a pentacene derivative is formed into a film by a vapor deposition method or the like, and a film of a polymeric compound or high molecular compound such as a polythiophene derivative is formed from a solution. Examples concerning the manufacturing method of semiconductor devices having organic thin film transistors include those described, for example, in JP-A No. 2004-80026. This example has been adopted a device for restricting the amount of the organic semiconductor material to be used by use of a capillary phenomenon.

Recently, the film forming method has further been developed and research and development for reducing the cost has been proceeded further by manufacturing the channel portion of a TFT with a small amount of organic semiconductor material with no loss thereby reducing the cost by using a printing process typically represented by an ink jet method, a micro-dispensing method or a transfer method. In addition, research and development for manufacturing electrodes or interconnections with printing have also been started.

### SUMMARY OF THE INVENTION

As described above, the TFT manufacturing method using the printing technique has a feature capable of reducing the cost. However, the positional accuracy is about 20 μm in the current printing technique and it is about several μm even by the use of a modern technique. In view of such restriction, it is difficult to manufacture TFT having a fine pattern. In particular, if positional displacement is caused between a gate electrode (lower electrode) and a source/drain electrode (upper electrode), there arises a problem of lowering of the moveability of an organic semiconductor or the like. It is considered that the positional displacement occurs in the ink jet method during the flying of a material jetted from a nozzle to a substrate. It is also considered that the displacement occurs during the transfer of a material from a transfer roll to a substrate in a transfer method.

The current preparation method adopts a printing step for the steps of forming organic semiconductor films and interconnections, a conventional semiconductor step for the formation of insulators or contact holes, and a printing or conventional semiconductor step for formation of electrodes. In this case, since both of the systems are combined with each other, manufacturing apparatus include various equipment such as apparatus concerned with photolithography, printing apparatus, film forming apparatus, etching apparatus, etc., and photomasks are necessary in the step of forming contact holes, electrodes, etc., which increases the production cost.

In view of the various problems described above, it is an object of the present invention to provide an organic thin film transistor having a fine pattern shape and electrodes in which a lower electrode and an upper electrode are self-aligned accurately to each other and opposed to each other by way of an insulator without using a photomask by using only the printing method.

The present invention particularly intends to provide a method of manufacturing a semiconductor device having an organic thin film transistor in which the device is formed by using a printing technique, and an upper electrode is disposed to be in self-alignment with the lower electrode by using a photolithographic step by the exposure from the rear face using the lower electrode as a mask and a lift off step.

The gist of a typical embodiment of the invention is as described below. That is, the invention adopts a manufacturing method of applying a photolithographic step not using a photomask only for the positioning step for an upper electrode and a lower electrode, and using a printing method for the other steps. A nontranslucent gate electrode (lower electrode) is prepared by using a translucent substrate and printing and baking a conductive material on the translucent substrate (lower electrode). Then, a translucent insulator, and a positive type photoresist are stacked successively by a printing method for a necessary area. Then, the photoresist is exposed from the rear face of the substrate using the lower electrode as a mask. Then, by conducting development, a resist pattern can be formed only just above the lower electrode. In this case, an appropriate heat treatment is conducted optionally upon formation of the resist pattern. A conductive material is printed and baked overriding the resist pattern. Then, the conductive material just above the lower electrode is lifted off together with the resist pattern by pealing off the resist pattern. Thus, accurate alignment between the lower electrode and the upper electrode can be attained. Then, an organic semiconductor material is printed just above the lower electrode to form an organic thin film transistor.

### BRIEF DESCRIPTION OF THE DRAWINGS

FIG. 1A is a plan view of a transistor in Example 1 of the invention, the transistor being illustrated in the order of its manufacturing steps;

FIG. 1B is a cross-sectional view of the transistor in Example 1 of the invention, the transistor being illustrated in the order of its manufacturing steps;

FIG. 2A is a plan view of the transistor in Example 1 of the invention, the transistor being illustrated in the order of its manufacturing steps;

FIG. 2B is a cross-sectional view of the transistor in Example 1 of the invention, the transistor being illustrated in the order of its manufacturing steps;

FIG. 3A is a plan view of the transistor in Example 1 of the invention, the transistor being illustrated in the order of its manufacturing steps;

FIG. 3B is a cross-sectional view of the transistor in Example 1 of the invention, the transistor being illustrated in the order of its manufacturing steps;

FIG. 4A is a plan view of the transistor in Example 1 of the invention, the transistor being illustrated in the order of its manufacturing steps;

FIG. 4B is a cross-sectional view of the transistor in Example 1 of the invention, the transistor being illustrated in the order of its manufacturing steps;

FIG. 5A is a plan view of the transistor in Example 1 of the invention, the transistor being illustrated in the order of its manufacturing steps;

FIG. 5B is a cross-sectional view of the transistor in Example 1 of the invention, the transistor being illustrated in the order of its manufacturing steps;

FIG. 6A is a plan view of the transistor in Example 1 of the invention, the transistor being illustrated in the order of its manufacturing steps;

FIG. 6B is a cross-sectional view of the transistor in Example 1 of the invention, the transistor being illustrated in the order of its manufacturing steps;

FIG. 7A is a plan view of the transistor in Example 1 of the invention, the transistor being illustrated in the order of its manufacturing steps;

FIG. 7B is a cross-sectional view of the transistor in Example 1 of the invention, the transistor being illustrated in the order of its manufacturing steps;

FIG. 8A is a plan view of the transistor in Example 1 of the invention, the transistor being illustrated in the order of its manufacturing steps;

FIG. 8B is a cross-sectional view of the transistor in Example 1 of the invention, the transistor being illustrated in the order of its manufacturing steps;

FIG. 9A is a plan view of the transistor in Example 1 of the invention, the transistor being illustrated in the order of its manufacturing steps;

FIG. 9B is a cross-sectional view of the transistor in Example 1 of the invention, the transistor being illustrated in the order of its manufacturing steps;

FIG. 10A is a plane view of the semiconductor device having a transistor in Example 2 of the invention, the semiconductor device being illustrated in the order of its manufacturing steps;

FIG. 10B is a cross-sectional view of the semiconductor device having the transistor in Example 2 of the invention, the semiconductor device being illustrated in the order of its manufacturing steps;

FIG. 11A is a plane view of the semiconductor device having the transistor in Example 2 of the invention, the semiconductor device being illustrated in the order of its manufacturing steps;

FIG. 11B is a cross-sectional view of the semiconductor device having the transistor in Example 2 of the invention, the semiconductor device being illustrated in the order of its manufacturing steps;

FIG. 12A is a plan view of a transistor in Example 3 of the invention, the transistor being illustrated in the order of its manufacturing steps;

FIG. 12B is a cross-sectional view of the transistor in Example 3 of the invention, the transistor being illustrated in the order of its manufacturing steps;

FIG. 13A is a plan view of the transistor in Example 1 of the invention, the transistor being illustrated in the order of its manufacturing steps;

FIG. 13B is a cross-sectional view of the transistor in Example 3 of the invention, the transistor being illustrated in the order of its manufacturing steps;

FIG. 14A is a plan view of the transistor in Example 3 of the invention, the transistor being illustrated in the order of its manufacturing steps;

FIG. 14B is a cross-sectional view of the transistor in Example 3 of the invention, the transistor being illustrated in the order of its manufacturing steps;

FIG. 15A is a plan view of the transistor in Example 3 of the invention, the transistor being illustrated in the order of its manufacturing steps;

FIG. 15B is a cross-sectional view of the transistor in Example 3 of the invention, the transistor being illustrated in the order of its manufacturing steps;

FIG. 16A is a plan view of the transistor in Example 3 of the invention, the transistor being illustrated in the order of its manufacturing steps;

FIG. 16B is a cross-sectional view of the transistor in Example 3 of the invention, the transistor being illustrated in the order of its manufacturing steps;

FIG. 17A is a plan view of a transistor in Example 4 of the invention, the transistor being illustrated in the order of its manufacturing steps;

FIG. 17B is a cross-sectional view of the transistor in Example 1 of the invention, the transistor being illustrated in the order of its manufacturing steps;

FIG. 18A is a plan view of the transistor in Example 4 of the invention, the transistor being illustrated in the order of its manufacturing steps;

FIG. 18B is a cross-sectional view of the transistor in Example 4 of the invention, the transistor being illustrated in the order of its manufacturing steps;

FIG. 19A is a plan view of the transistor in Example 4 of the invention, the transistor being illustrated in the order of its manufacturing steps;

FIG. 19B is a cross-sectional view of the transistor in Example 4 of the invention, the transistor being illustrated in the order of its manufacturing steps;

FIG. 20A is a plan view of the transistor in Example 4 of the invention, the transistor being illustrated in the order of its manufacturing steps;

FIG. 20B is a cross-sectional view of the transistor in Example 4 of the invention, the transistor being illustrated in the order of its manufacturing steps;

FIG. 21A is a plan view of the transistor in Example 4 of the invention, the transistor being illustrated in the order of its manufacturing steps;

FIG. 21B is a cross-sectional view of the transistor in Example 4 of the invention, the transistor being illustrated in the order of its manufacturing steps;

FIG. 22A is a plan view of the transistor in Example 4 of the invention, the transistor being illustrated in the order of its manufacturing steps;

FIG. 22B is a cross-sectional view of the transistor in Example 4 of the invention, the transistor being illustrated in the order of its manufacturing steps;

FIG. 23A is a plan view of the transistor in Example 4 of the invention, the transistor being illustrated in the order of its manufacturing steps;

FIG. 23B is a cross-sectional view of the transistor in Example 4 of the invention, the transistor being illustrated in the order of its manufacturing steps;

FIG. 24A is a plane view showing a structure of a transistor as a comparative example.

FIG. 24B is a cross-sectional view showing the structure of the transistor as the comparative example.

### DETAILED DESCRIPTION OF THE PREFERRED EMBODIMENTS

Principal configurations of the present invention and specific materials used therefor are to be described specifically prior to specific descriptions of various configurations of the invention.

The gist of the invention resides in a method of manufacturing an organic thin film transistor having, on a substrate comprising a translucent material, a channel portion comprising an organic semiconductor, an insulator comprising a translucent material in contact with the channel portion, a gate electrode comprising a non-translucent material in contact with the insulator, and a pair of source and drain regions spaced apart through the channel portion, in which the ends of the pair of both source and drain electrodes are determined on the side of the gate electrode by photolithography by exposure from the rear face of the substrate to a photoresist layer using the gate electrode as a mask region. Preferably, the channel portion, the insulator, the gate electrode and the source and drain electrodes are formed by a printing method.

An example of the step of photolithography for determining the ends of the pair of source and drain electrodes on the side of the gate electrode will be described below. That is, the photolithographic step includes a step of forming a nontranslucent gate electrode over a translucent substrate, a step of forming a gate insulator covering at least the gate electrode, a step of forming a photoresist film including at least a region corresponding to a channel region, a step of applying exposure from the side of the translucent substrate, a step of developing the photoresist film after the exposure, a step of forming an electrode material layer covering at least the photoresist film remaining after the development, and a step of forming an organic semiconductor layer for forming a channel portion.

Specific examples typically include the following two methods. That is, in the first method, the step of forming the organic semiconductor film is executed before the step of forming the electrode material layer. In the second method, the step of forming the organic semiconductor film is executed after the step of forming the electrode material layer.

In order to attain the object of the invention, it is more preferred that any of the steps of forming the nontranslucent gate electrode, forming the gate insulator, and forming the electrode material layer at least over the gate insulator is conducted by using a printing method.

Exposure from the rear face of the translucent substrate typically includes examples in which: exposure light is a high pressure mercury lamp g-line (436 nm) and a photoresist used for the photolithography has sensitivity to the high pressure mercury lamp g-line (436 nm); the exposure light is high-pressure mercury lamp i-line (365 nm) and a photoresist used for the photolithography has sensitivity to the high pressure mercury lamp i-line (365 nm); the light is a KrF excimer laser light (248 nm), and a photoresist used for the photolithography has sensitivity to the KrF excimer laser light (248 nm); the light is an ArF excimer laser light (193 nm) and a photoresist used for the photolithography has sensitivity to the ArF excimer laser light (193 nm).

Typical examples of the printing method include an ink jet method, a micro-dispensing method, and a transfer method. It is practical to use at least one of them for forming portions for the purpose of the invention.

An example of typical steps in the invention is to be shown. A first example is as described below. That is, this includes the steps of forming a nontranslucent gate electrode above a translucent substrate, forming a gate insulator covering at least the gate electrode, forming a photoresist film including at least a region corresponding to the channel region, exposing light from the side of the translucent substrate, developing the photoresist film after the exposure, forming an electrode material layer covering at least the photoresist film remaining after the development, removing the photoresist film remaining after the development, and forming an organic semiconductor layer for forming the channel portion.

The second example will be described below. That is, this includes the steps of forming a nontranslucent gate electrode above the translucent substrate, forming a gate insulator covering the gate electrode, forming an organic semiconductor layer containing at least a region corresponding to the channel region, forming a photoresist film containing at least a region corresponding to the channel region above the organic semiconductor layer, applying exposure from the side of the translucent substrate, developing the photoresist film after the exposure, and forming an electrode material layer covering at least the photoresist film remaining after the development.

Then, specific materials used in the invention will be described.

Typical examples of the translucent substrate are formed of silicon compounds or organic compounds. Further, specific examples of the translucent substrate include glass plates, and flexible resin sheets, the so-called plastic films. The material for the plastic film can include, for example, polyethylene terephthalate, polyethylene naphthalate, polyether imide, polyether sulfone, polyether ketone, polyphenylene sulfide, polyacrylate, polyimide, polycarbonate, cellulose triacetate, and cellulose acetate propionate. The plastic film has a feature capable of bending flexibly. This is advantageous to various application uses in which a flexible property is required for the device.

The conductive material is ink in the form of super fine particles, complexes and polymers comprising metals, metal oxides or conductive polymeric materials capable of forming a liquid material being dispersed in a solvent.

The translucent insulator material comprises organic insulative polymers and its examples include polyimide derivatives, benzocyclobutene derivatives, polyacrylic derivatives, polystyrene derivatives, polyvinyl phenol derivatives, polyester derivatives, polycarbonate derivatives, polyvinyl acetate derivatives, polyurethane derivatives, polysulfone derivatives, acrylate resins, acrylic resins, and epoxy resins.

Examples of the organic semiconductor material include polyacene derivatives such as pentacene, polythiophene derivatives, polyethylene vinylene derivatives, polypyrrole derivatives, polyisothianaphthalene derivatives, polyaniline derivatives, polyacetylene derivatives, polydiacetylene derivatives, polyazulene derivatives, polypyrene derivatives, polycarbazole derivatives, polyselenophene derivatives, polybenzofurane derivatives, polyphenylene derivatives, polyindole derivatives, polypyridazine derivatives, metal phthalocyanie derivatives, fullerene derivatives, and polymers or oligomers formed by mixing two or more of such repetitive units. Optionally, the organic semiconductor materials may be subjected to a doping treatment. Further, to improve the performance of the organic semiconductor transistor, a surface treatment may also be applied to the adhesion surface between the organic semiconductor and the substrate by the step before printing of the organic semiconductor.

As the resist pealing solution used in the lift-off step, a peeling solution used exclusively for each resist may be used, or an organic solvent to which the resist is soluble may also be used. In a case of an aqueous alkali solution developing type resist, an aqueous alkali solution with high concentration may also be used. The concentration of the alkali used herein is from 5% by weight to 50% by weight. The optimal concentration is from 10% by weight to 20% by weight. Examples of the organic solvent usable herein include a resist solvent such as methyl amyl ketone, ethylacetate, cyclohexanone, propylene-glycol-monomethylether, and propylene-glycol-1-monomethylether-2-acetate, ethers such as acetone and tetrahydrofuran, toluene, and chloroform. Examples of the aqueous alkali solution usable herein include aqueous solution of potassium hydroxide, aqueous solution of sodium hydroxide, tetra-n-methyl ammonium hydroxide, aqueous solution of tetra-n-ethyl ammonium hydroxide, aqueous solution of tetra-n-propyl ammonium hydroxide, and aqueous solution of tetra-n-butyl ammonium hydroxide.

Then, several examples of the invention will be described specifically. In the examples, since the ink jet printing apparatus used has both a positional accuracy of and a minimum value of a drawing line of 20 μm, the linear width of the gate electrode is set to 20 μm.

### EXAMPLE 1

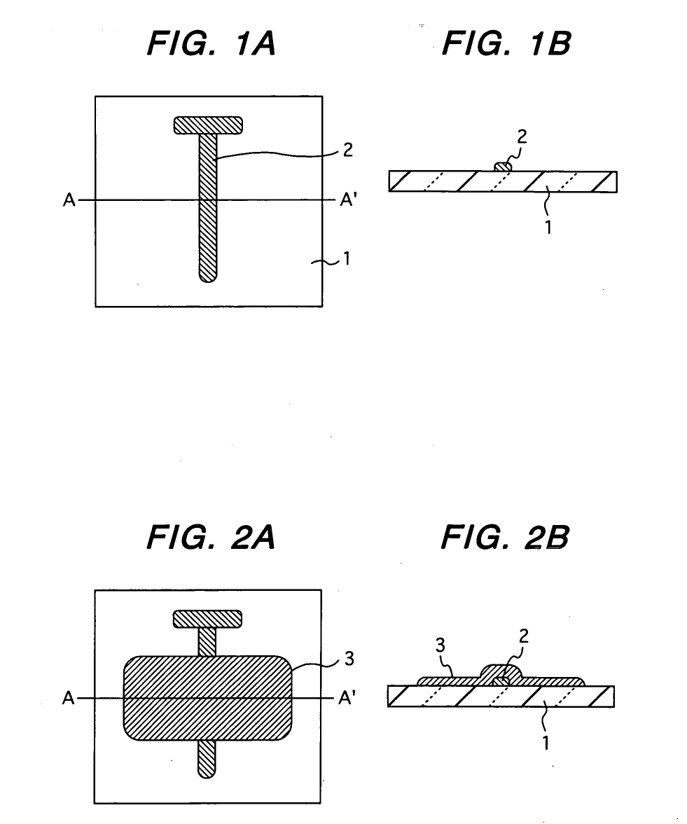

FIGS. 1A to 9A are plan views and FIGS. 1B to 9B are cross-sectional views taken along line A-A′ of corresponding FIGS. 1A to 9A. The figures each show a device in an example in the order of its manufacturing steps.

Polyethylene terephthalate as an organic compound was used as a translucent substrate 1, and gold-nano-particles dispersed in a chloroform solution were used as ink and a gate electrode shape of 20-μm line width was printed by an ink jet printing method, and heated at 120° C. for 5 min to form a gold gate electrode 2. (Plane view: FIG. 1A, cross-sectional view: FIG. 1B). The height of the formed gate electrode was about 10 μm. The grain size of metal nuclei of the gold-nano-particles was 3.5 nm, and the periphery of the metal nuclei was covered with butane thiolate. The gold gate electrode 2 in the plan view of FIG. 1A is formed in a T-shape, that is, it is drawn to be two vertical and lateral portions. The gold gate electrode 2 is integrally formed of these portions to constitute a gate electrode portion. It is optional whether the T-shaped portion is formed as an integral portion or formed as at least two portions and the manufacturing method is suitable or not suitable depending on the cases. The ink jet printing of this example is more suitable to the method of scanning the two portions divisionally. On the other hand, the transfer method or the like is advantageous to the method of transferring the T-shaped part as an integral form. In each of the following plan views, for example, FIGS. 2A through 6A (although all drawing numbers are not illustrated hereinafter), the T-shaped part is drawn as separated into the two portions in the drawings under the same situation.

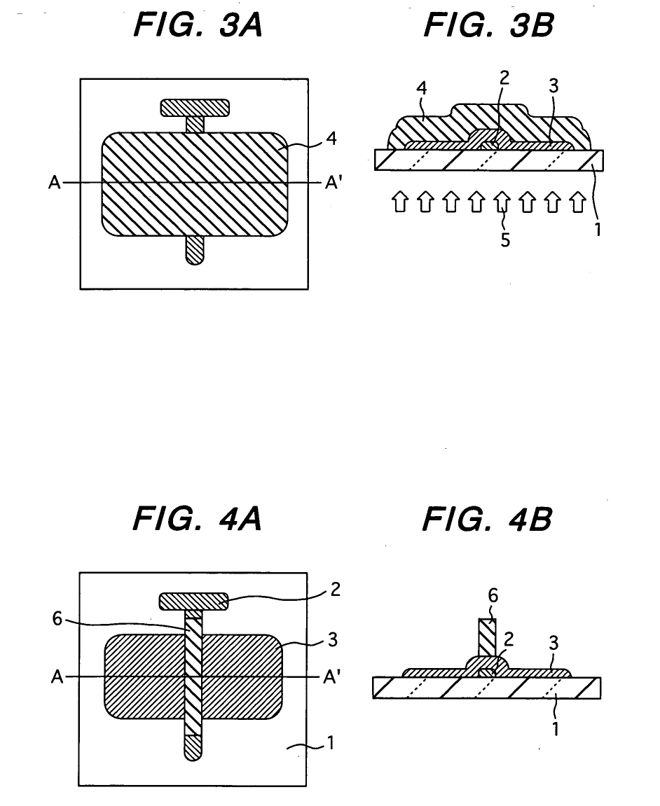

Then, 10% N-methylpyrrolidone solution of polyimide was used to form the shape of a gate insulator by an ink jet printing method, and heat treatment was applied at 150° C. for 20 min to form an gate insulator 3 at a necessary portion (plan view: FIG. 2A, cross sectional view: FIG. 2B). The thickness of the gate insulator 3 was about 100 nm. Further, in view of possible positional displacement, it was patterned larger by about 20 μm than the width of source/drain electrode to be formed subsequently. A positive type i-line resist 4 was printed over the same by an ink jet method and a heat treatment was applied to it at 120° C. for 5 min. The printing pattern was formed larger by 30 μm than the gate insulator in view of a possible printing displacement of 20 μm. The thickness of the resist film was about 20 μm. After the heat treatment, exposure was conducted for about 30 sec from the rear face of the substrate by using a high-pressure mercury lamp (i-line: 365 nm) 5 (plan view: FIG. 3A, cross-sectional view: FIG. 3B). Then, development was conducted for 90 sec by a liquid developer. A resist pattern 6 aligned with the gate electrode was formed just above the gate electrode 2 (plan view: FIG. 4A, cross-sectional view: FIG. 4B).

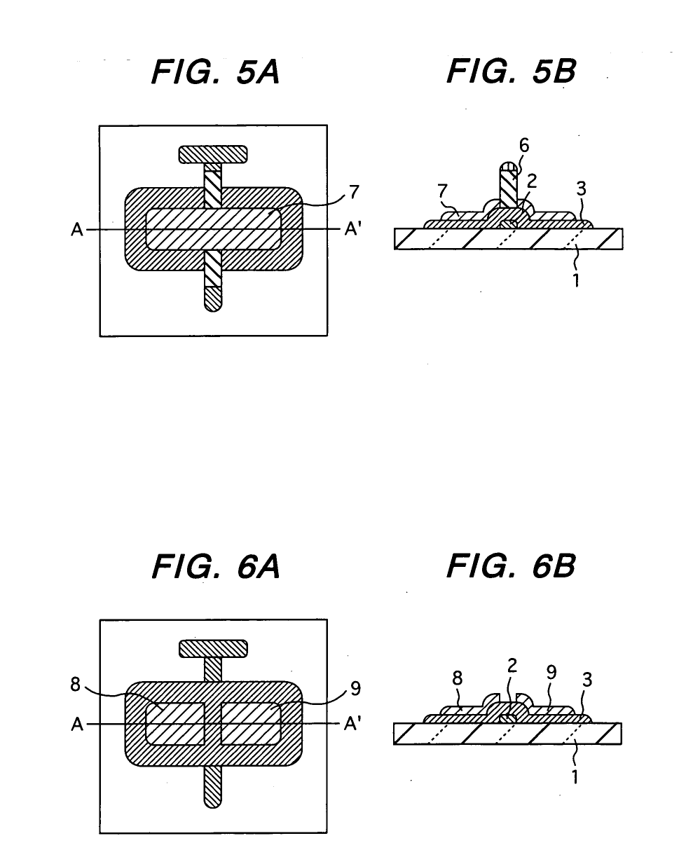

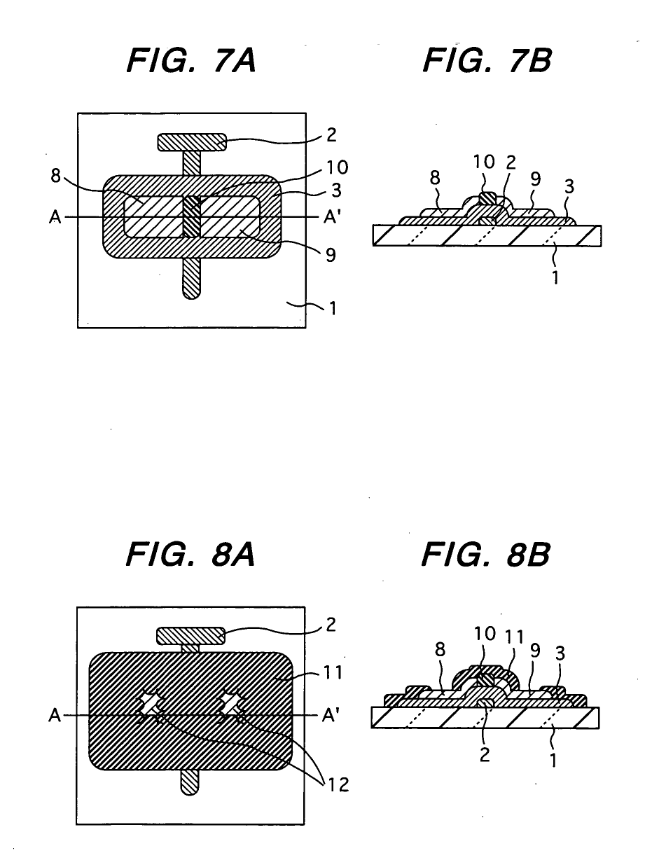

Then, using the same chloroform solution of gold-nano-particles as in the gate electrode, a source/drain electrode 7 was printed by using an ink jet printing method so as to override the resist pattern 6 and heat treatment was applied to it at 120° C. for 5 min (plan view: FIG. 5A, cross-sectional view: FIG. 5B). In this case, the source/drain electrode (upper electrode) 7 was formed such that the length of the channel portion was 100 μm. The thickness of the upper electrode was 0.5 μm. Successively, a substrate shown in FIG. 5A was dipped for 5 min in tetrahydrofuran/acetone (at 1/1) solution and the upper electrode just above the gate was lifted off together with the resist pattern 6 to form a source electrode 8 and a drain electrode 9 (plane view: FIG. 6A, cross-sectional view: FIG. 6B). The positional displacement between the source electrode 8/drain electrode 9, and the gate electrode 2 thus formed was as small as 20 nm. Then, a channel portion 10 was printed between the source electrode 8 and the drain electrode 9 just above the gate electrode 2 by using an organic semiconductor (Poly(3-hexylthiophene-2.5-diyl) Regioregular) as a 5% chloroform solution by an ink jet printing method and a heat treatment was applied to it at 100° C. for 2 min. (plan view: FIG. 7A, cross-sectional view: FIG. 7B). The thickness of the channel portion 10 was 15 μm.

Then, a film 11 that serves both as an insulator and a passivation film was formed so as to cover the source electrode 8, the gate electrode 9, and the organic semiconductor channel portion 10 by using the same solution as that for the gate insulator 3 by an ink jet printing method and a heat treatment. In this case, not-printed portions 12 were left for interconnection from the source electrode 8 and the drain electrode 9 (plan view: FIG. 8A, cross-sectional view: FIG. 8B). Each of the not-printed portions 12 was formed in a square shape of 50 μm×50 μm at the central portion of the source electrode 8 or the drain electrode 9. The thickness of the film 11 was 10 μm.

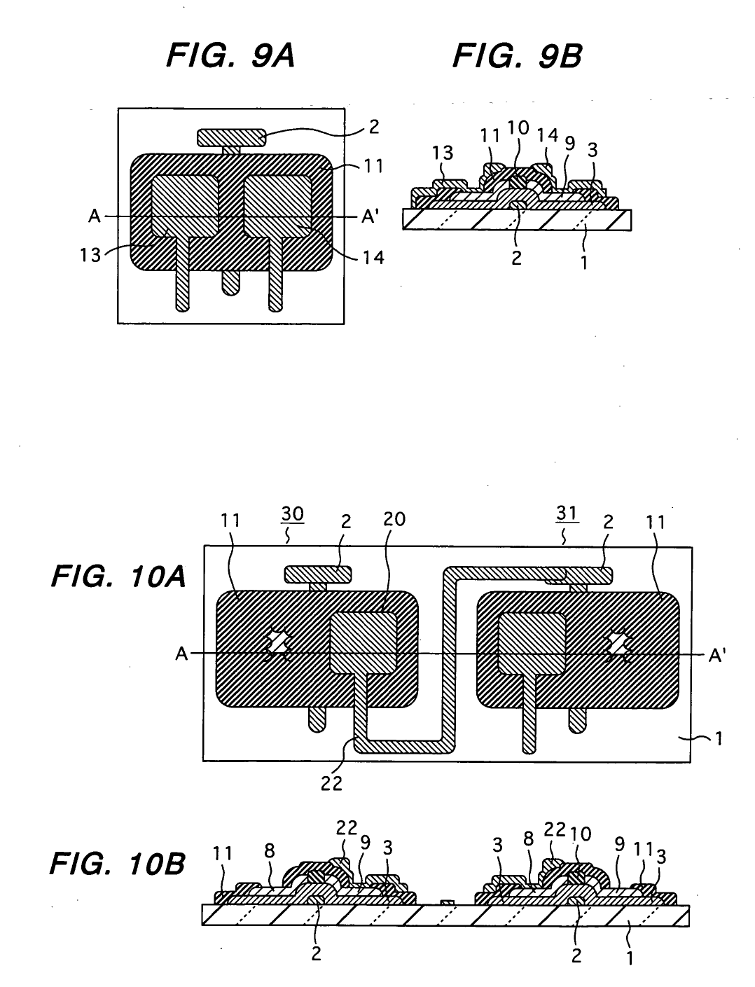

Finally, an interconnection 13 from the source electrode 8 and an interconnection 14 from the drain electrode 9 were formed by the same procedure as in the formation of the gate electrode 2 (plan view: FIG. 9A, cross-sectional view: FIG. 9B). The thickness of each of the interconnection 13 and the interconnection 14 was 15 μm.

When the moveability of the transistor was measured, it was 0.61 cm²/Vs. The value is a characteristic of an organic thin film transistor that is considered that there is no positional displacement between both of the upper and lower electrodes.

The insulator 3, the resist layer 4 and the organic semiconductor layer 10 can be formed also by spin coating. The moveability of the organic thin film transistor by the spin coating method was almost equal to that of the printing method. However, the printing method described above is advantageous as compared with a case of forming the transistor by the spin coating because there is no wasteful loss in the amount of each solution to be used.

Further, the insulator 11 can be formed also by spin coating. The moveability of the organic thin film transistor by a spin coating method was almost equal to that of the printing method. However, the printing method described above is advantageous as compared with a case of forming the transistor by the spin coating because there was no wasteful loss in the amount of each solution to be used. Further, the printing method is also advantageous in the formation of the contact hole 12 in view of mass production because of saving the increase in the number of steps such as photolithography and etching steps. In the formation of the upper electrode (plan view: FIG. 5A, cross-sectional view: FIG. 5B), the gold electrode 7 can be formed by sputter vapor deposition using a stencil mask instead of printing the gold-nano-particles. As a result, the positional displacement between the gate electrode 2, and the source electrode 8 and the drain electrode 9 was satisfactorily as small as 20 nm. However, the printing method has no worry of causing displacement in the positional alignment of the stencil mask and is advantageous in view of the number of steps and the cost in mass production.

Further, instead of printing the gold-nano-particles, the upper electrode can also be formed by forming a conductive film as an electrode over the entire surface of the substrate and then removing the conductive film in the unnecessary region. However, since this requires to conduct a photolithographic step requiring the mask for removing the conductive film in the unnecessary region, this increases the number of steps and the cost. On the contrary, in the printing method described above, since the electrode can be formed at an optional region, the pattern for the source electrode 8 and the drain electrode 9 can be formed without causing positional displacement.

As the solvent during lifting-off in the steps of FIGS. 6A and 6B, a 1/1 solution of tetrahydrofran/acetone is preferred. This is free from the draw back in view of the mass production in a case of using only the acetone that taking of much lift-off time or in the case of using only the tetrahydrofuran causing pealing of the electrode.

### EXAMPLE 2

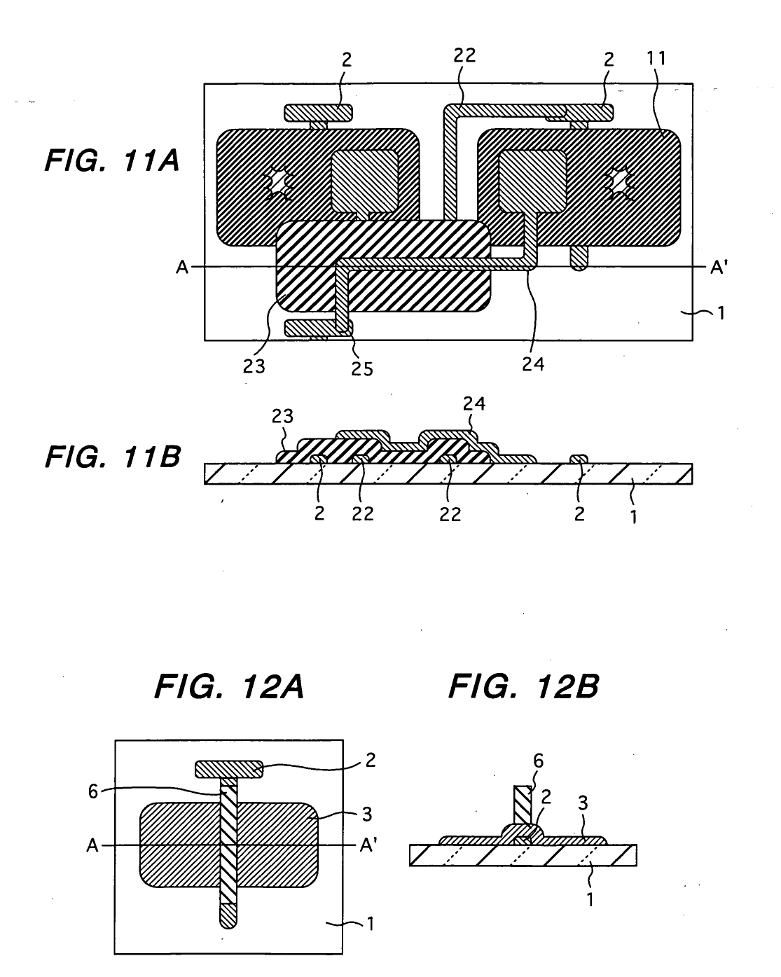

This is an example of forming two organic semiconductor transistors 30, 31 by the same method as in Example 1. FIGS. 10A and 11A are plan views of this example and FIGS. 10B and 11B are cross-sectional views of the same, taken along line A-A′ of corresponding FIGS. 10A and 11A. The method of forming each of the transistors is the same as that in Example 1 described above. However, a drain electrode 20 of a first transistor 30 and a second gate electrode 2 of the other transistor 31 are connected by interconnection 22 after formation of each of the transistors in the constitution of this example.

Further, FIG. 11 shows an example in which the interconnection from the second transistor is connected with a third gate electrode 25 of a third transistor. An insulator 23 is formed over an interconnection 22 by the same procedure as in the film 11 of Example 1 in the device of FIG. 10A. An interconnection 24 is formed above the insulator 23. Then the interconnection 24 is connected with a third gate electrode 25.

### EXAMPLE 3

This shows an example of forming an interconnection from each of the electrodes simultaneously upon formation of the source electrode 8 and the drain electrode 9 in Example 1.

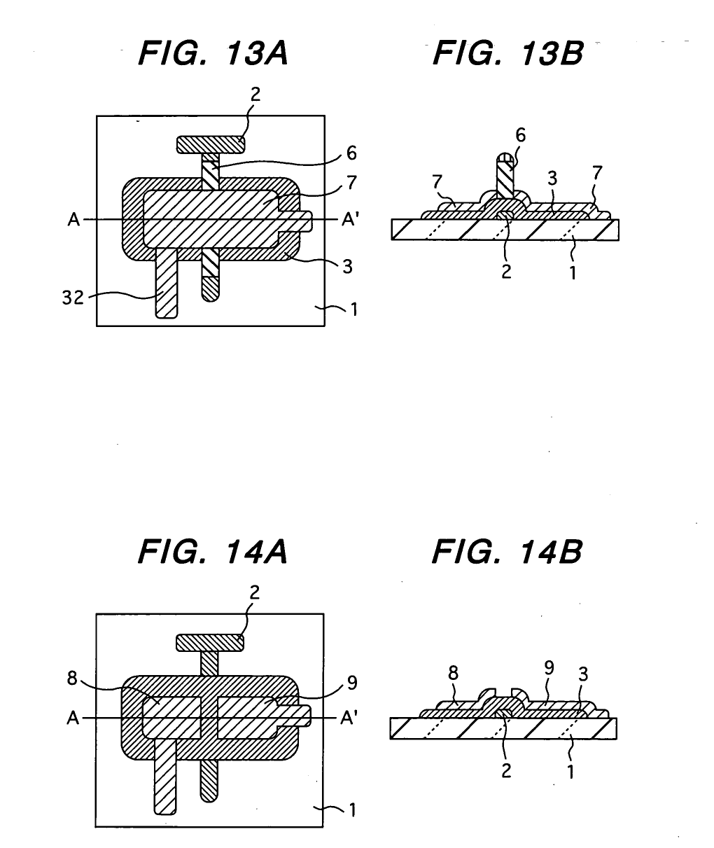

By the same procedures as those in Example 1, a gate electrode 2, a gate insulator 3, and a resist pattern 6 are formed (plan view: FIG. 12A, cross-sectional view: FIG. 12B). Then, by using the same method and with the same solution of the gold-nano-particles as in Example 1, an upper electrode 7 is formed by ink jet printing and a heat treatment. In this case, an interconnection pattern 32 from the upper electrode 7 is also formed by ink jet printing (plan view: FIG. 13A, cross-sectional view: FIG. 13B). The interconnection pattern 32 had a line width of 20 μm. Then, by the same method as in Example 1, the resist 6 just above the gate electrode 2 and a portion of the upper electrode 7 were lifted off (plan view: FIG. 14A, cross-sectional view: FIG. 14B).

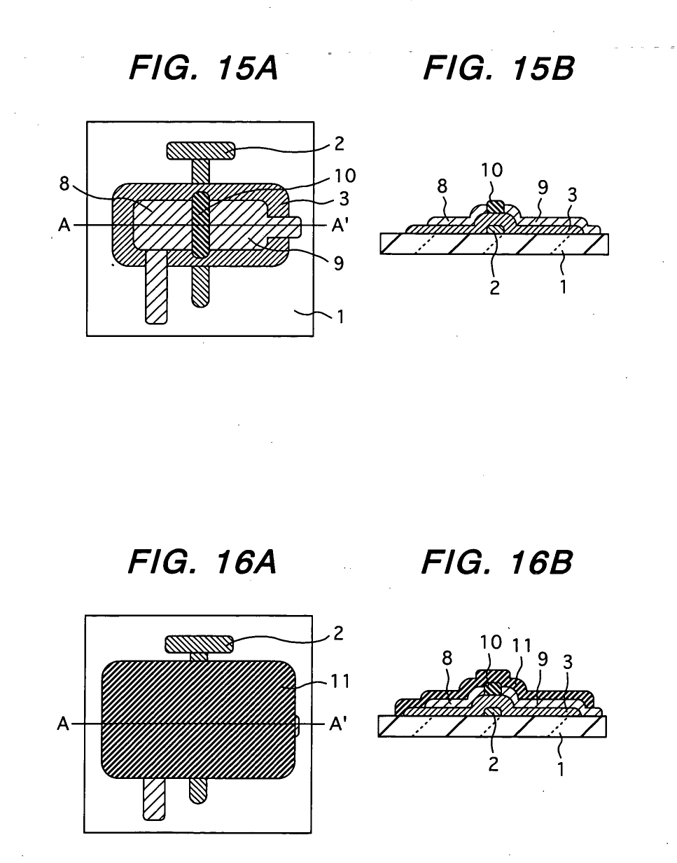

Then, a channel portion 10 was formed by the same method and with the same organic semiconductor as in Example 1 (plane view: FIG. 15A, cross-sectional view: FIG. 15B). Then, an insulator 11 was formed in the same method as in Example 1 (plan view: FIG. 16A, cross-sectional view: FIG. 16B).

When the moveability of the transistor was determined, it was 0.62 cm²/Vs. As compared with an organic thin film transistor manufactured with no positional displacement for each of portions, comparable results can be obtained. Further, when compared with Example 1, an organic thin film transistor of the same moveability can be formed with the steps minus one step.

### EXAMPLE 4

In Examples 1 to 3, the organic semiconductor film 10 was formed after formation of the source electrode 8 and the drain electrode 9. In this example, the organic semiconductor film 10 is formed before formation of the source electrode 8 and the drain electrode 9.

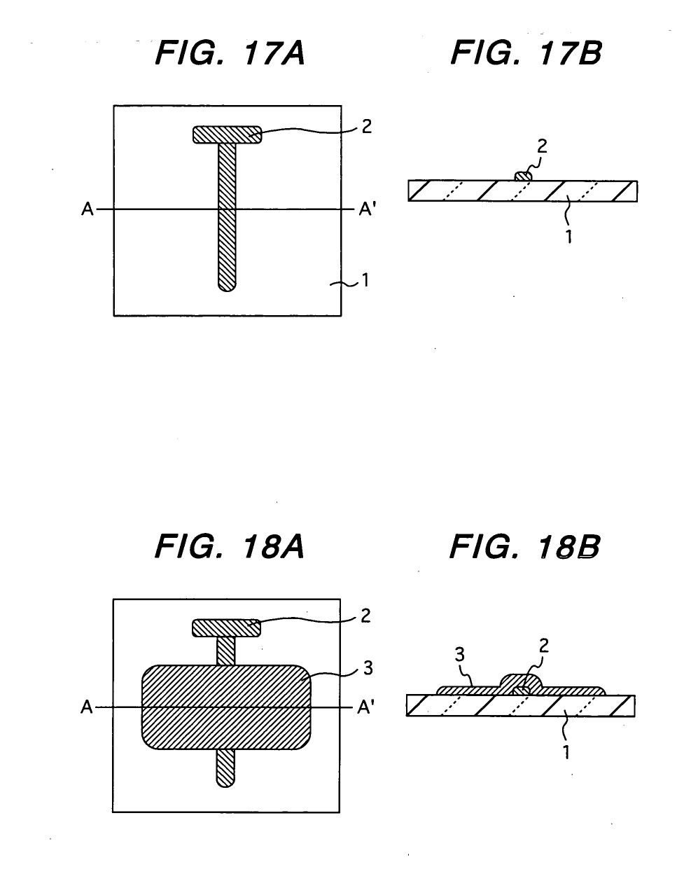

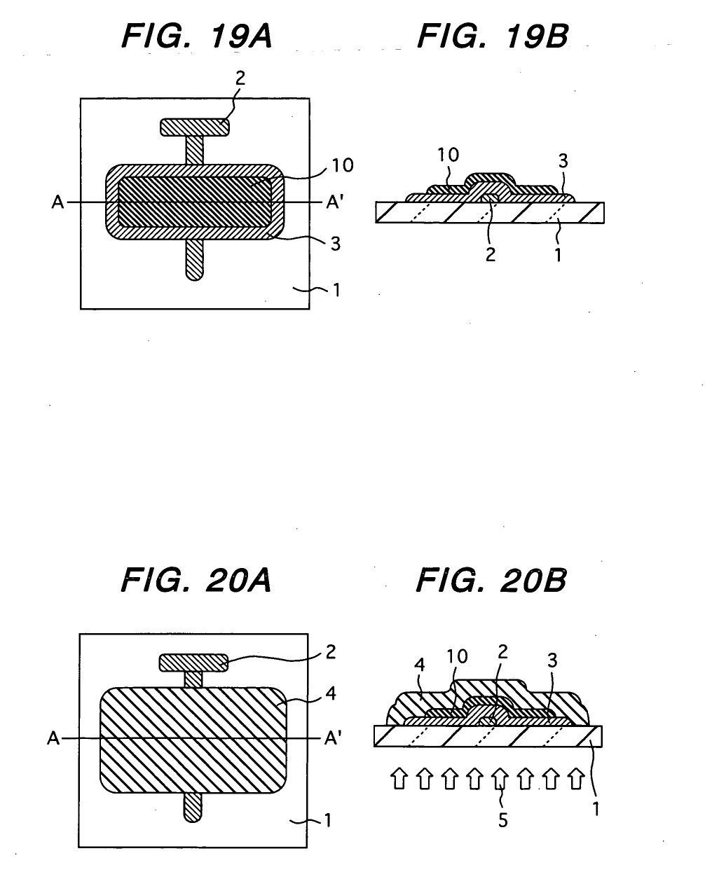

Basic manufacturing steps are the same as those in Example 1. A gate electrode 2 was formed over a translucent substrate 1 (plan view: FIG. 17A, cross-sectional view: FIG. 17B), and a gate insulation film 3 was formed (plan view: FIG. 18A, cross-sectional view: FIG. 18B). Then, an organic semiconductor film 10 was formed to a size smaller than the gate insulator 3 by using a solution of an organic semiconductor (plan view: FIG. 19A, cross-sectional view: FIG. 19B). The thickness of the organic semiconductor film 10 was 15 μm.

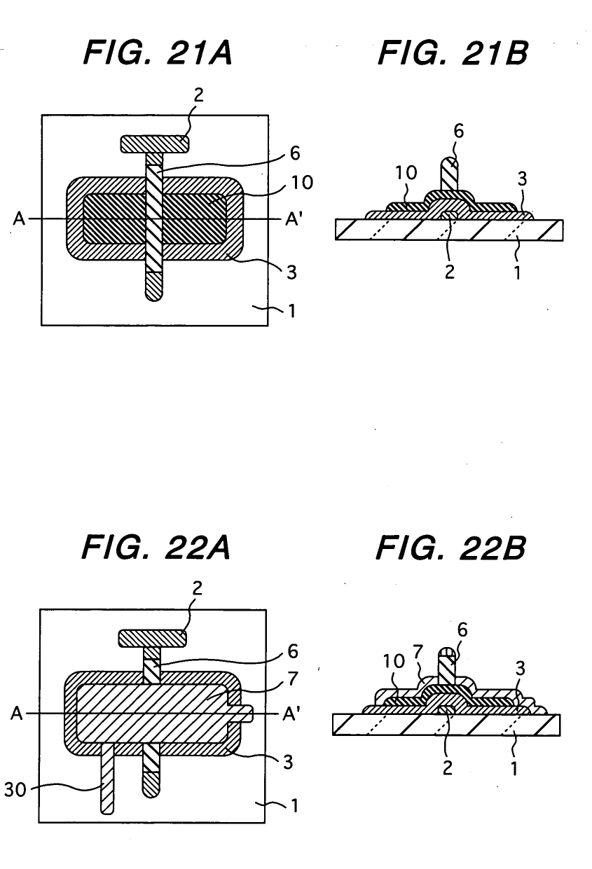

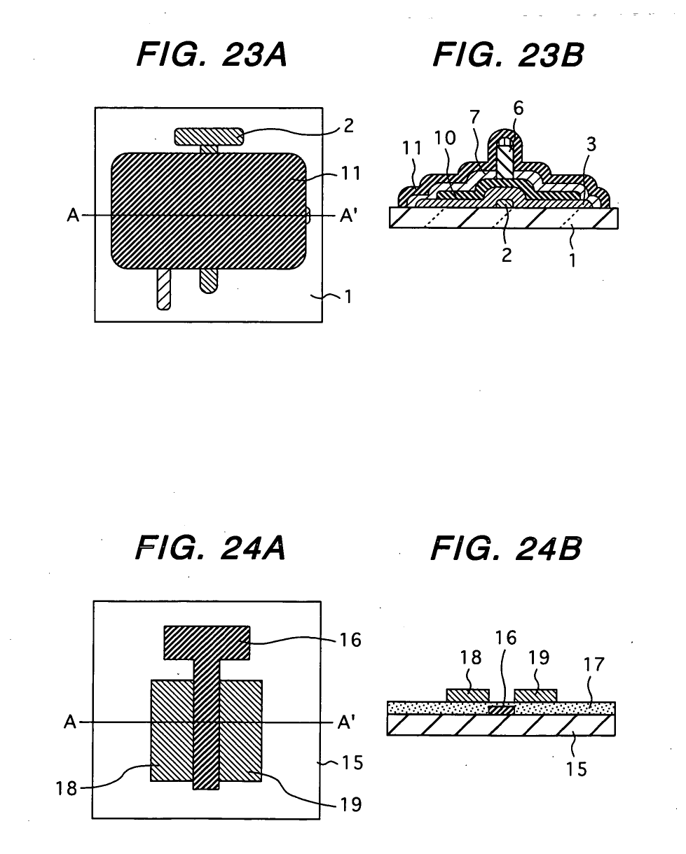

Then, a resist 4 was formed and exposure was conducted from the rear face (plan view: FIG. 20A, cross-sectional view: FIG. 20B). Then, the resist layer was developed to form a resist pattern 6 (plan view: FIG. 21A, cross-sectional view: FIG. 21B). Then, an electrode 7 is formed and, at the same time, an interconnection 32 was also formed like in Example 4 (plan view: FIG. 22A, cross-sectional view: FIG. 22B). An insulator 11 was formed to complete a transistor (plan view: FIG. 23A, cross-sectional view: FIG. 23B).

When the moveability of the transistor was measured, it was 0.66 cm²/Vs. For the performance of the organic thin film transistor manufactured only by the printing step, a comparable result was obtained as compared with an organic thin film transistor manufactured with no positional displacement for each of the portions. Further, the transistor can be formed by the steps with the number of steps being decreased by two.

Also in this example, it is of course possible to peel the resist pattern 6 before formation of the insulator 11. However, the step described above of leaving the resist pattern 6 is preferred since the organic semiconductor layer 10 is not degraded.

Examples 1 to 4 described above show typical examples which were particularly high in the performance both in the cost and the performance. Various examples with modification of materials, etc. from the examples described above are to be described.

[Substrate]

An organic thin film transistor was formed quite in the same manner as in Example 1 except for using a glass substrate as a silicon compound instead of a translucent substrate in Example 1. The moveability of the transistor was 0.60 cm²/Vs which was comparable with that in the plastic substrate.

[Conductive Material]

A transistor was formed quite in the same manner as in Example 1 except for using silver-nano-particles instead of gold-nano-particles in Example 1. The moveability of the transistor was 0.55 cm²/Vs. The moveability was 0.61 cm²/Vs in a case of using platinum-nano-particles and the moveability was 0.62 cm²/Vs in a case of using copper-nano-particles, which showed performance comparable with that using the gold-nano-particles. For each of the materials described above, while there is a difference in view of characteristics due to the difference of the work function, for example, between gold and silver, the purpose of the present invention can be attained sufficiently. Among the materials, the gold-nano-particles are most advantageous with various points of view such as performance, easy of synthesis, cost and, further store stability.

[Organic Semiconductor Material]

A transistor was formed quite in the same manner as in Example 1 except for changing the solution for gold-nano-particles in Example 1, for example, with a polyaniline solution doped, for example, with emeraldine salt. The moveability of the transistor was 0.55 cm²/Vs. Such an example can also attain the object of the present invention sufficiently.

Further, a transistor was formed by using a 1.3 wt % aqueous solution of poly(styrene sulfonate)/poly(s,3-dihydrothieno-[3,4-b]-1,4-dioxin). The moveability of the transistor was 0.45 cm²/Vs. This example is somewhat advantageous in view of the cost.

[Insulator]

In a case of using a 0.5% xylene solution of epoxidized polybutadiene for the insulator of Example 1, the moveability was 0.61 cm²/Vs. The value is substantially identical with the value of Example 1. This example is somewhat advantageous in view of the cost.

Further, the moveability in a case of using a 2% methyl amyl ketone solution of polyhydroxystyrene for the insulator, was 0.55 cm²/Vs and the object of the invention can be attained. Polyhydroxystyrene in this example is inexpensive and has an advantage capable of using methyl amyl ketone as a safe solvent.

[Resist]

A transistor was formed quite in the same manner as in Example 1 except for changing the i-line resist 4 to a g-line resist and changing the exposure light 5 to a high pressure mercury lamp g-line in Example 1. As a result, the positional displacement between the gate electrode 2, and the source electrode 8 and the drain electrode 9 was about 40 nm, and the object of the invention can be attained. Further, in a case of changing the i-line resist 4 to a KrF resist and changing the exposure light to a KrF excimer laser light in Example 1, the positional displacement between the gate electrode 2, and the source electrode 8 and the drain electrode 9 was 18 nm and the moveability was 0.64 cm²/Vs, and the result equal to that in Example 1 was obtained. Further, in a case of changing the i-line resist 4 to an ArF resist and changing the exposure light 5 to a KrF excimer laser light in Example 1, the positional displacement between the gate electrode 2, and the source electrode 8 and the drain electrode 9 was 18 nm and the moveability was 0.64 cm²/Vs, and the result equal to that in Example 1 was obtained.

Several examples of the materials have been described above specifically.

The present invention has been described above specifically. According to the invention, in the step of manufacturing an organic semiconductor, (1) a necessary material is drawn in a necessary area by a printing method, and (2) a portion necessary for positional alignment between a lower electrode and an upper electrode are formed by positional alignment by self-aligning an upper electrode while using a lower electrode per se as a photomask and using a photolithographic step. Accordingly, an electrode substrate in which the lower electrode and the upper electrode are accurately positioned by way of an insulator using the printing method can be formed. When the printing method according to the invention is used, the necessary material may be used only for the required minimum area and, in addition, no photomasks are required and etching steps such as for preparation of through holes are not required. Accordingly, the manufacturing cost can be saved greatly.

In the invention, since all of the steps can be conducted at low temperatures for formation, even in a case where a substrate is formed of a material such as a plastic material which is flexible and has a thermoplasticity capable of thermally deforming, the upper interconnection/electrode can be formed in self-alignment with the lower electrode. Use of such substrate is suitable as a substrate for preparing a display, for example, electronic paper.

### COMPARATIVE EXAMPLE 1

For easy understanding of the feature of the manufacturing method according to the invention, a typical existent method of manufacturing an organic thin film transistor is shown as a comparative example. FIG. 24A is a plane view of this comparative example and FIG. 24B is a cross-sectional view thereof. An aluminum gate electrode 16 was formed over a silicon substrate 15 by using a photolithographic step, and a silicon oxide film 17 of 200 nm thick was formed as a gate insulator. Further, a source electrode 18 and a drain electrode 19 positionally aligned with the gate electrode 16 were formed further on the upper surface of the gate insulator by photolithography and lifting off using a photomask. A film was formed on the substrate 15 from poly(3-hexylthiophene-2.5-diyl) Regioregular in 5% chloroform solution by a spin coating method at 1000 rpm for 60 sec and a heat treatment at 100° C. for 2 min, to form an organic thin film transistor. In the comparative example. The source electrode 18 and the drain electrode 19 were positionally aligned with the previously formed gate electrode 16 and were formed by using an additional photolithographic step.

According to the present invention, it is possible to provide a semiconductor device having an organic thin film transistor having an electrode in which a lower electrode and an upper electrode are positioned accurately with respect to each other by way of an insulator by using the printing method.

### DESCRIPTION OF REFERENCES

1 . . . substrate, 2 . . . lower electrode, gate inter connection/electrode, 3 . . . gate insulator, 4 . . . resist, 5 exposure light, 6 . . . resist pattern, 7 . . . upper electrode, 8 . . . upper electrode, source electrode, 9 . . . upper electrode, drain electrode, 10 . . . organic semiconductor, 11 . . . insulator, 12 . . . through hole for interconnection, 13 . . . interconnection, 14 . . . interconnection, 15 . . . silicon substrate, 16 . . . gate electrode, 17 . . . gate insulator, 18 source electrode, 19 . . . drain electrode, 20 . . . source electrode, drain electrode, 21 . . . gate electrode, 22 . . . interconnection, 23 . . . insulator, 24 . . . interconnection, 25 . . . gate electrode, 30 . . . transistor, 31 . . . transistor, 32 . . . interconnection.

What is claimed is:

1. A method of manufacturing a semiconductor device comprising an organic semiconductor film having a channel portion constituted with an organic semiconductor, a translucent insulator in contact with the channel portion, a nontranslucent gate electrode in contact with the insulator, and a pair of source and drain electrodes spaced apart through the channel portion,
wherein ends of the pair of source and drain electrodes on a side of the gate electrode are determined by photolithography by exposure from a rear face of the substrate by using the gate electrode as a mask region for a photoresist layer.

2. A method of manufacturing having an organic semiconductor film according to claim 1, wherein the channel portion, the insulator, the gate electrode, the source and the drain electrodes are formed by a printing method.

3. A method of manufacturing a semiconductor device having an organic semiconductor film according to claim 1, wherein the photolithographic steps for determining the ends of the pair of source and drain electrodes on the side of the gate electrode includes the steps of:
forming a nontranslucent gate electrode above a translucent substrate;
forming a gate insulator covering at least the gate electrode;
forming a photoresist film at least including a region corresponding to at least the channel region;
applying exposure from the side of the translucent substrate;
developing the photoresist film after the exposure;
forming an electrode material layer covering at least the photoresist film remaining after the development; and
forming an organic semiconductor layer for forming the channel portion.

4. A method of manufacturing a semiconductor device having an organic semiconductor film according to claim 3, wherein the step of forming the organic semiconductor film is conducted before the step of forming the electrode material layer.

5. A method of manufacturing a semiconductor device having an organic semiconductor film according to claim 3, wherein the step of forming the organic semiconductor film is conducted after the step of forming the electrode material layer.

6. A method of manufacturing a semiconductor device having an organic semiconductor film according to claim 3, wherein each of the steps of forming the nontranslucent gate electrode, forming the gate insulator, and forming the electrode material layer over at least the gate insulator is conducted by using a printing method.

7. A method of manufacturing a semiconductor device having an organic semiconductor film according to claim 3, wherein the translucent substrate is a flexible substrate.

8. A method of manufacturing a semiconductor device having an organic semiconductor film according to claim 3, wherein the translucent substrate comprises a silicon compound.

9. A method of manufacturing a semiconductor device having an organic semiconductor film according to claim 3, wherein the translucent substrate comprises an organic compound.

10. A method of manufacturing a semiconductor device having an organic semiconductor film according to claim 3, wherein the exposure light from the rear face of the translucent substrate is a high pressure mercury lamp g-line (436 nm), and the photoresist used for the photolithography has sensitivity to the high pressure mercury lamp g-line (436 nm).

11. A method of manufacturing a semiconductor device having an organic semiconductor film according to claim 3, wherein the exposure light from the rear face of the translucent substrate is a high pressure mercury lamp i-line (365 nm) and the photoresist used for the photolithography has sensitivity to the high pressure mercury lamp i-line (365 nm).

12. A method of manufacturing a semiconductor device having an organic semiconductor film according to claim 3, wherein the exposure light from the rear face of the translucent substrate is KrF excimer laser light (248 nm) and the photoresist used for the photolithography has sensitivity to the KrF excimer laser light (248 nm).

13. A method of manufacturing a semiconductor device having an organic semiconductor film according to claim 3, wherein the exposure light from the rear face of the translucent substrate is a ArF excimer laser light (193 nm) and the photoresist used for the photolithography has sensitivity to the ArF excimer laser light (193 nm).

14. A method of manufacturing a semiconductor device having an organic semiconductor film according to claim 4, wherein the printing method uses at least one method selected from the group consisting of an ink jet method, a micro-dispensing method and a transfer method.

15. A method of manufacturing a semiconductor device having an organic semiconductor film, comprising the steps of:
forming a nontranslucent gate electrode above a translucent substrate;
forming a gate insulator covering at least the gate electrode;
forming a photoresist film including at least a region corresponding to a channel region;
applying exposure from the side of the translucent substrate;
developing the photoresist film after the exposure;
forming an electrode material layer covering at least the photoresist film remaining after the development;
removing the photoresist film remaining after the development; and
forming an organic semiconductor layer for forming a channel portion.

16. A method of manufacturing a semiconductor device having an organic semiconductor film, comprising the steps of:
forming a translucent gate electrode above a translucent substrate;
forming a gate insulator covering the gate electrode;
forming an organic semiconductor layer including at least a region corresponding to a channel region;
forming a photoresist film including at least a region corresponding to the channel region above the organic semiconductor layer;
applying exposure from the side of the translucent substrate;
developing the photoresist film after the exposure; and
forming an electrode material layer at least covering the photoresist film remaining after the development.
